(19) United States
(12) Patent Application Publication
(10) Pub. No.: US 2011/0214726 A1
(43) Pub. Date: Sep. 8, 2011

(54) Ultra- High Solar Conversion Efficiency for Solar Fuels and Solar Electricity via Multiple Exciton Generation in Quantum Dots Coupled with Solar Concentration

(75) Inventors: Arthur J. NOZIK, Boulder, CO (US); Mark HANNA, Boulder, CO (US)

(73) Assignee: ALLIANCE FOR SUSTAINABLE ENERGY, LLC, Golden, CO (US)

(21) Appl. No.: 13/039,168

(22) Filed: Mar. 2, 2011

Related U.S. Application Data
(60) Provisional application No. 61/309,598, filed on Mar. 2, 2010.

(51) Int. Cl. H01L 31/0232; H01L 31/06; B82Y 99/00

(52) U.S. Cl. 136/255; 136/259; 977/948

(57) ABSTRACT

Photoconversion devices comprising a semiconductor region of nanostructured crystalline material are disclosed. The nanostructures of a crystalline material provide for the generation of multiple excitons per photon absorbed by the crystalline nanostructure in response to incident solar radiation. The photoconversion devices will also include one or more optical elements providing for the concentration of sunlight in the semiconductor region. Also disclosed are photoconversion methods, systems and apparatus featuring the combination solar concentration with nanostructures of a crystalline material providing for the generation of multiple excitons per photon absorbed by the crystalline nanostructure in response to incident solar radiation.

### PRIORITY

This application claims the benefit under 35 USC section 119 of U.S. provisional application 61/309,598 filed on Mar. 2, 2010 and entitled “Ultra-High Solar Conversion Efficiency for Solar Fuels and Solar Electricity via Multiple Exciton Generation in Quantum Dots Coupled with Solar Concentration,” the content of which is hereby incorporated by reference in its entirety and for all purposes.

### CONTRACTUAL ORIGIN

The United States Government has rights in this invention under Contract No. DE-AC36-08G028308 between the United States Department of Energy and the Alliance for Sustainable Energy, LLC, the manager and operator of the National Renewable Energy Laboratory.

### BACKGROUND

An important long range objective of solar energy research is the discovery and development of photoconversion materials, processes, and architectures that can produce solar electricity or liquid and gaseous solar fuels at costs competitive with the cost of energy derived from fossil fuels such as petroleum, natural gas, or coal. In general, solar electricity and solar fuel generation systems will require relatively high conversion efficiencies to be cost competitive with fossil fuel. For example a cost competitive photovoltaic device is projected to require conversion efficiencies of greater than 30% coupled with capital costs of less than $150/m².

Photoconversion materials may, in general, be utilized in two distinct manners to provide useable energy. In the first instance, photoconversion materials may be used to create useable electric current directly. Conventional photovoltaic devices are representative of this first type of technology. A photovoltaic device, commonly referred to a solar cell or solar panel, converts incident sunlight into electrical current which may then be used to power any type of electrical system or stored in batteries. Semiconductor materials in bulk form currently dominate the field of commercial photovoltaic (PV) power. More sophisticated materials and architectures having higher efficiencies are being developed.

Alternatively, photoconversion materials may be used to create an internal electrical current which is then substantially contemporaneously used without the use of external wires connected to an electrochemical converter to produce a liquid or gaseous fuel. This type of process is defined herein as a solar fuel generation process. Solar fuel generation, for example the direct conversion of CO₂ and/or H₂O to fuels, such as H₂, syngas, alcohols, hydrocarbons or carbohydrates is now receiving a high degree of interest and support. Unlike the case with photovoltaic power, no solar fuels industry exists today. Traditional biofuels may be distinguished from solar fuels as defined above. Biofuels are derived from solar irradiance driving biological photosynthesis and the production of biofuels is a present day industry. Traditional biofuels however, such as ethanol derived from agricultural products, are not included under the definition of solar fuels used herein because the production of biofuels is a non-contemporaneous two-step process. Biofuels production first involves plant photosynthesis followed by conversion of biomass to a useable fuel via dark processes such as fermentation or thermal refining.

All solar fuels reactions are endoergic and thus require energy to drive the reaction forward. The energy required is nearly the same for many important and relevant solar fuel reactions, in particular, about 1.2 eV per electron transferred during the oxidation-reduction (redox) reactions. Photovoltaic devices rely upon incident energy in the form of sunlight to produce useable electricity. When the input energy is provided by light for either type of conversion, a large fraction of the energy input is light from the visible part of the solar spectrum, for example red wavelengths of less than 600-700 nm. Photovoltaic cells also utilize light in the near-infrared region, for example 1200 nm to 700 nm. As noted above, photovoltaic energy production will become more commercially competitive if devices can be created having conversion efficiencies equal to or greater than 30%; in addition, the higher the efficiency the higher the cost per unit area that can be tolerated for the photovoltaic converter and still maintain a net energy cost lower than that derived from fossil fuels. Solar fuel reactions will also become commercially important if greater photoconversion efficiencies can be achieved.

The methods and devices disclosed herein are directed toward photoconversion materials having enhanced conversion efficiencies that are suitable for implementation in photovoltaic devices or solar fuel generation devices, systems, apparatus and methodologies.

The foregoing examples of the related art and limitations related therewith are intended to be illustrative and not exclusive. Other limitations of the related art will become apparent to those of skill in the art upon a reading of the specification and a study of the drawings.

### SUMMARY OF THE EMBODIMENTS

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

One embodiment includes a photoconversion device comprising a semiconductor region of nanostructured crystalline material. The nanostructures of a crystalline material provide for the generation of multiple excitons per absorbed photon interacting with the crystalline nanostructure in response to incident solar radiation. The photoconversion device will also include one or more optical elements providing for the concentration of sunlight in the semiconductor region.

The nanostructures of crystalline material may comprise at least one of semiconductor quantum dots, quantum wires or quantum rods. The optical element or optical elements provide for the 50 to1000 fold concentration of sunlight intensity in the semiconductor region.

The photoconversion device may be a photovoltaic (PV) cell configured to generate electrical energy. Alternatively, the photoconversion device may be a solar fuel generation device used to create an internal electrical current which is then substantially contemporaneously used to produce a liquid or gaseous fuel. In either type of device the semiconductor region may include one, two or multiple nanocrystalline semiconductor junctions having different band gaps arranged in a tandem or other sequence.

In embodiments where the photoconversion device is a solar fuel generation device, the device may further comprise a source of a gas or liquid phase material which is converted to fuel through an endoergic electrochemical oxidation-reduction reaction. In addition, such a device will include one or more electrodes in fluid communication with the source of gas or liquid phase material. The electrodes in turn must be connected in electrical communication with the semiconductor region such that the semiconductor region provides current to the electrodes in response to incident solar radiation to drive the endoergic fuel production reaction.

In selected embodiments of a solar fuel cell photoconversion device, the electrodes may have a total surface area greater than or equal to the total surface area of the concentrator optics. A seal may also be included to isolate the semiconductor region from contact with the gas or liquid phase material as well as to provide for transport of dissociated electrons and holes away from the semiconductor region. An electrocatalyst may be operatively associated with at least one of the one or more electrodes.

Alternative embodiments include methods of semiconductor based photoconversion. One method comprises providing a semiconductor region comprising nanostructures of a crystalline material. In addition, one or more optical elements configured to concentrate sunlight in the semiconductor region are provided. The method further comprises illuminating the semiconductor region with concentrated sunlight causing the generation of multiple excitons per photon interacting with the crystalline nanostructure. The method may further comprise dissociating excitons to form free carriers and collecting the free characters. In an alternative method, the free characters are collected as a photogenerated current. The photogenerated current may be used or stored, for example in a battery or device connected in a circuit with a PV cell or other embodiment. Alternatively, the photogenerated current may substantially contemporaneously drive an endoergic fuel producing reaction within a solar fuel producing embodiment.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIG. 1 is a schematic diagram showing Multiple Exciton Generation (MEG) in a quantum dot.

FIG. 2 is a graphic representation of Shockley-Queisser (SQ) detailed balance thermodynamic calculations of the maximum possible conversion efficiency in the radiative limit for conventional solar cells compared to QD solar cells exhibiting MEG.

FIG. 3A is a schematic diagram of an exemplary photoconversion cell featuring an array of quantum dots that are electronically coupled to provide electronic transport.

FIG. 3B is a schematic diagram of an exemplary photoconversion cell featuring QD-sensitized nanocrystalline TiO₂ layers wherein the QDs are isolated from each other.

FIG. 3C is a schematic diagram of an exemplary photoconversion cell featuring QDs dispersed in an organic semiconductor polymer matrix with a blend of electron and hole-conducting phases that accepts electrons or holes from the QDs and transports them to the cell contact regions to produce fuel through oxidation-reduction reactions or to generate electrical power.

FIG. 4 is a graphic representation of conversion efficiency vs. a band gap for different values of cell overvoltage.

FIG. 5 is a graphic representation of conversion efficiencies in tandem cells with two different bandgaps.

FIG. 6 is a graphic representation of water splitting efficiency at one sun as a function of cell overvoltage for both cells with one photoelectrode (bottom curve) and two photoelectrodes (top curves).

FIG. 7 is a graphic representation of different MEG characteristics.

FIG. 8 is a graphic representation of different MEG characteristics defined as the MEG quantum yield as a function of absorbed photon energy normalized by the QD bandgap.

FIG. 9 is a graphic representation of the relationship between conversion efficiency, solar concentration, and optimum QD band gap.

FIG. 10 is a contour plot representation of maximum water splitting efficiency of a double band gap tandem water splitting cell for different values of band gap with a solar concentration of 1000× and a cell overvoltage of zero volts.

FIG. 11 is a contour plot representation of maximum water splitting efficiency of a double band gap tandem water splitting cell for different values of band gap with a solar concentration of 500× and a cell overvoltage of zero volts.

FIG. 12 is a contour plot representation of maximum water splitting efficiency of a double band gap tandem water splitting cell for different values of band gap with a solar concentration of 500× and a cell overvoltage of 0.6 volts.

FIG. 13 is a schematic representation of a solar fuel producing system featuring the coupling of MEG in QD solar devices with solar concentration.

### DETAILED DESCRIPTION

Unless otherwise indicated, all numbers expressing quantities of ingredients, dimensions, reaction conditions and so forth used in the specification and claims are to be understood as being modified in all instances by the term “about.”

In this application and the claims, the use of the singular includes the plural unless specifically stated otherwise. In addition, use of “or” means “and/or” unless stated otherwise. Moreover, the use of the term “including”, as well as other forms, such as “includes” and “included”, is not limiting. Also, terms such as “element” or “component” encompass both elements and components comprising one unit and elements and components that comprise more than one unit unless specifically stated otherwise.

### MEG in Nanostructured Crystalline Materials

Useable electricity can be produced from photovoltaic (PV) cells including a semiconductor photoconverter of greater or lesser efficiency. Alternatively, a device including a semiconductor photoconverter can produce internally photogenerated current which is utilized substantially contemporaneously to drive a fuel generation reaction. Exemplary methods and device embodiments disclosed herein describe how very high conversion efficiencies can be obtained for solar photovoltaic cells or solar fuel generation devices using semiconductor regions composed of nanostructures of crystalline materials in conjunction with solar concentration. As defined herein a nanostructure of a crystalline material is a structure where the spatial confinement of electrons and holes causes the e⁻ and h⁺ pairs to be correlated and thus exist initially as excitons rather than free carriers. For practical application in a photovoltaic cell or for solar fuels production the excitons must be subsequently dissociated into free electrons and free holes and spatially separated. Representative nanostructures of a crystalline material include but are not limited to quantum dots (QDs); quantum wires (QWs) and quantum rods (QRs).

The spatial confinement of electrons and holes in quantum dots and other crystalline nanostructures causes several important effects: (1) the e⁻ and h³⁰ pairs are correlated and thus exist as excitons rather than free carriers, (2) the rate of hot electron and hole (i.e., exciton) cooling can be slowed because of the formation of discrete electronic states, (3) momentum is not a good quantum number and thus the need to conserve crystal momentum is relaxed, and (4) auger processes are greatly enhanced because of increased e⁻-h⁺ Coulomb interaction. Because of these factors it has been observed that the production of multiple e⁻-h⁺ pairs will be enhanced in nanostructures of a crystalline material compared to bulk semiconductors.

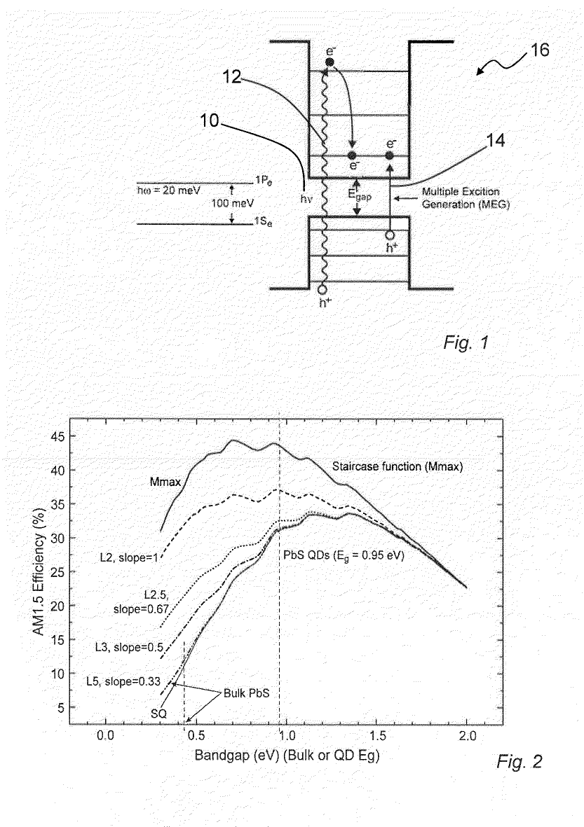

In particular, both the threshold energy (hυₜₕ) for electron hole pair multiplication (EHPM) and its efficiency, η_{EHPM} (defined as the number of excitons produced per additional bandgap of energy above the EHPM threshold energy) are expected to be greatly enhanced in QD type material. The formation of multiple excitons is denominated herein as Multiple Exciton Generation (MEG). Free carriers can only form upon dissociation of the excitons in various PV devices or solar fuel producing structures. The possibility of enhanced MEG in QDs was first proposed in 2001. The original concept is shown in FIG. 1, where a single photon 10 is illustrated as creating two e⁻-h⁺ pairs 12 and 14 respectively within the confined structure of a QD 16. FIG. 2 presents Shockley-Queisser (S-Q) detailed balance calculations in the radiative limit for conventional solar cells compared to QD solar cells exhibiting various MEG characteristics regarding the threshold photon energy hυₜₕ for the MEG process to begin and η_{EHPM}, the efficiency of the MEG process, defined as the number of excitons produced per absorbed photon after the MEG process is initiated.

Multiexcitons have been detected using several spectroscopic measurements which are consistent with each other. For example, the first method used was to monitor the signature of multiple exciton generation using transient (pump-probe) absorption (TA) spectroscopy. The first experimental report of exciton multiplication for PbSe NCs reported an excitation energy threshold for the efficient formation of two excitons per photon at 3E_{g}. Subsequent work has reported that the threshold energy for MEG in PbSe QDs is 2E_{g}¹ Additional experiments observing MEG have now been reported for QDs of PbS, CdS, PbTe, InAs, Si, InP, CdTe and CdSe/CdTe core-shell QDs. For InP QDs the MEG threshold was 2.1E_{g}.

However, a few published reports could not reproduce some of the early positive MEG results, or if MEG was indeed observed the efficiency was claimed to be much lower. For example, in one report MEG was claimed to be only equivalent to impact ionization in bulk materials. Thus, some controversy has arisen concerning the efficiency of MEG in QDs. The reason for this inconsistency has been attributed to the influence of QD surface treatments and surface chemistry on MEG dynamics compared to cooling dynamics, and in some cases to the effects of surface charge produced during transient pump-probe spectroscopic experiments to determine MEG quantum yields. The controversy has now been settled and MEG efficiencies as a function of absorbed photon energy have now been essentially agreed upon.

### General OD Cell Architecture Applicable to Various Embodiments

The various device and method embodiments disclosed herein feature the combination of solar concentration with multiple exciton generation (MEG) provided by suitable converter materials to yield very high conversion efficiencies. Devices leveraging the exceptional conversion efficiencies may be implemented for solar fuels production and for PV electricity. It is important to note that an unanticipated synergy is present when the two efficiency enhancing techniques of MEG and solar concentration are combined. In particular, as described in detail below, the combination of solar concentration with multiple exciton generation (MEG) may result in conversion efficiencies that would not be expected when compared to solar photoconversion cells with solar concentration but no MEG or MEG cells without concentration.

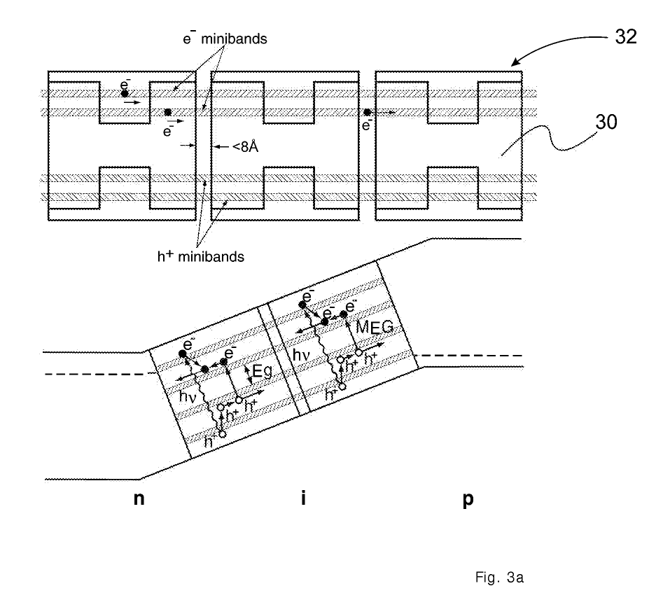

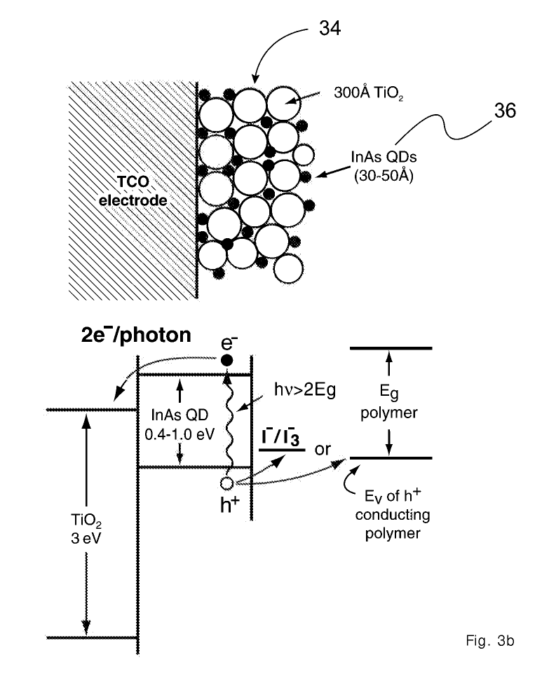

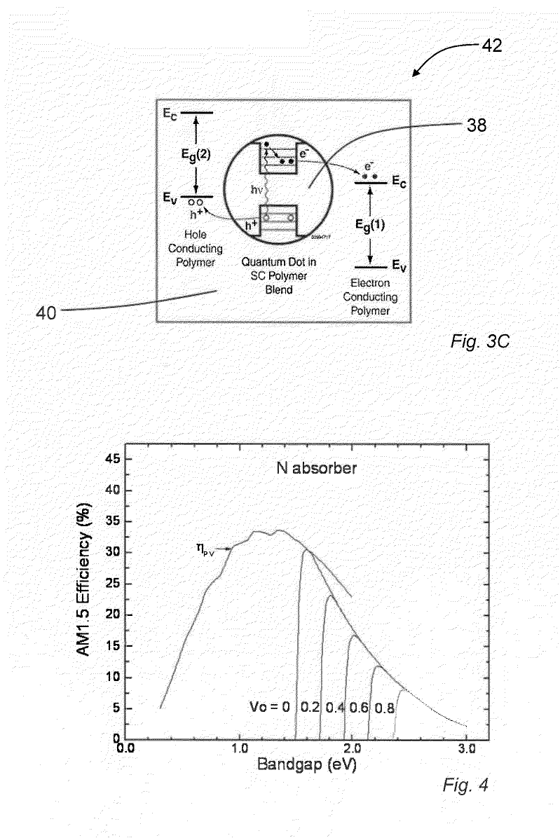

The described approach of combining a nanostructured MEG capable photoconverter with solar concentration produces efficiencies for solar fuel generation and PV electricity production that are 30% to 200% higher than conventional solar cells depending upon the degree of solar concentration and whether fuel or electricity is produced. A conversion efficiency enhancement of this magnitude could make the cost of solar fuels competitive with fossil fuels and greatly lower the cost of PV electricity as well. The fundamental pathway for enhancing conversion efficiency through increased photocurrent can be accessed, in principle, in three different generalized QD solar cell configurations. These configurations are schematically illustrated in FIGS. 3A-3C and described below. In addition to enhanced efficiency in PV cells, QDs, NCS, and exciton and/or carrier multiplication in semiconductor photoelectrodes could also enhance the efficiency of solar cells for solar fuels production. In this application, MEG effects in semiconductors can be implemented in photoelectrodes for more efficient direct water splitting cells, and QDs or NCs of different sizes and shapes can be used in two-junction tandem cells for highly efficient H₂O splitting to H₂ , and CO₂ reduction by H₂O to make liquid and gaseous fuels like alcohols and hydrocarbons.

### A. Photoelectrodes Composed of Quantum Dot Arrays

In one solar cell configuration (FIG. 3A), the QDs 30 are formed into an ordered 3-D array 32 with inter-QD spacing sufficiently small that strong electronic coupling occurs to allow long-range electron transport. If the QDs have the same size and are aligned, this system is a 3-D analog to a 1-D superlattice and the miniband structures formed therein. The moderately delocalized but still quantized 3-D states could be expected to produce MEG. Also, the slower carrier cooling and delocalized electrons could permit the transport and collection of hot carriers to produce a higher photopotential in a PV or solar fuel cell.

Significant progress has been made in forming 3-D arrays of both colloidal and epitaxial IV-VI, II-VI and III-V semiconductor alloy QDs. The former two systems have been formed via evaporation, crystallization, or self-assembly of colloidal QD solutions containing a reasonably uniform QD size distribution. Although the process can lead to close-packed QD films, they exhibit a significant degree of disorder. Concerning the III-V materials, arrays of epitaxial QDs have been formed by successive epitaxial deposition of epitaxial QD layers. After the first layer of epitaxial QDs is formed, successive layers tend to form with the QDs in each layer aligned on top of each other. Major issues are the nature of the electronic states as a function of inter-dot distance, array order versus disorder, QD orientation and shape, surface states, surface structure/passivation, and surface chemistry. Transport properties of QD arrays are also of critical importance.

### B. Quantum Dot-Sensitized Nanocrystalline TiO₂ Solar Cells

This alternative configuration (FIG. 3B) is a variation of a recent type of photovoltaic cell that is based on dye-sensitization of nanocrystalline TiO₂ layers. In this latter PV cell, dye molecules are chemisorbed onto the surface of 10-30 nm-size TiO₂ particles that have been sintered into a highly porous nanocrystalline 10-20 μm TiO₂ film 34. Upon photoexcitation of the dye molecules, electrons are very efficiently injected from the excited state of the dye into the conduction band of the TiO₂, affecting charge separation and producing a photovoltaic effect.

For the QD-sensitized cell, QDs 36 are substituted for the dye molecules; they can be adsorbed from a colloidal QD solution or produced in-situ. QDs made from InAs are shown as an example FIG. 3B but any semiconductor QD of appropriate size, bandgap, and shape can be used. Successful PV effects in such cells have been reported for several semiconductor QDs including InP, InAs, CdSe, CdS, and PbS. Group IV QDs such as Si, Ge, and SiGe alloys may also be utilized. Possible advantages of QDs over dye molecules are the tunability of optical properties with size and better heterojunction formation with solid hole conductors. Also, as discussed herein, a unique potential capability of the QD-sensitized solar cell is the production of quantum yields greater than one by MEG.

### C. Quantum Dots Dispersed in Organic Semiconductor Polymer Matrices

Recently, photovoltaic effects have been reported in structures consisting of QDs forming intimate junctions with organic semiconductor polymers. In one configuration, a disordered array of CdSe QDs is formed in a hole-conducting polymer, for example MEH-PPV {poly[2-methoxy, 5-(2′-ethyl)-hexyloxy-p-phenylenevinylene]}. Upon photoexcitation of the QDs, the photogenerated holes are injected into the MEH-PPV polymer phase, and are collected via an electrical contact to the polymer phase. The electrons remain in the CdSe QDs and are collected through diffusion and percolation in the nanocrystalline phase to an electrical contact to the QD network. Initial results show relatively low conversion efficiencies, but improvements have been reported with rod-like CdSe QD shapes embedded in poly(3-hexylthiophene) (the rod-like shape enhances electron transport through the nanocrystalline QD phase) and recently with newer polymers that allow for better electrical properties. In another configuration, a polycrystalline TiO₂ layer is used as the electron conducting phase, and MEH-PPV is used to conduct the holes; the electron and holes are injected into their respective transport mediums upon photoexcitation of the QDs.

A variation of these configurations is to disperse the QDs 38 into a blend of electron and hole-conducting polymers 40, as illustrated in FIG. 3C. It is also possible to use other electron-conducting materials, such as C60 or PCBM, as the electron-conducting phase in place of an electron-conducting polymer since the latter types of conducting polymers are not abundant and are more limited. This scheme is the inverse of light emitting diode structures based on QDs. In the PV cell 42, each type of carrier-transporting polymer would have a selective electrical contact to remove the respective charge carriers. A critical factor for success is to prevent electron-hole recombination at the interfaces of the two polymer blends; prevention of electron-hole recombination is also critical for the other QD configurations mentioned above.

### Solar Fuel Production

Several strategies are possible for the production of solar fuels. Of particular interest herein are (1) strategies that exploit photoconversion materials to produce electrical current to drive separate reactions such as water splitting to produce H₂ and/or solar CO₂ reduction to produce CO. In addition, if both H₂ and CO are produced, this creates syngas which can subsequently be converted into liquid and gaseous fuels through various dark reactions, such as Fischer-Tropsch chemistry. (2) The direct reduction of CO₂ with solar H₂ to alcohol fuel. (3) Alternatively, solar fuels can be produced via the direct solar photoreduction of CO₂ with water to alcohols, hydrocarbons, and ketones plus by-product O₂. This process is analogous to biological photosynthesis carried out by green plants.

It is important to note that the methods and devices disclosed herein may be suitable as the high efficiency photoconverter element of any type of PV cell or solar fuel production cell. The scope of the disclosure is not limited to the specific embodiments described in detail. Furthermore, a water splitting cell is described in detail below. This embodiment however is not limiting. The concepts detailed with respect to the water splitting cell are applicable to other types of solar fuel production cells and PV cells. Hence, the thermodynamics described in detail below with respect to a water splitting cell are valid for all solar fuels producing reactions

Quantum Dot MEG Photoconverters with Solar Concentration

Various device embodiments and photoconverter methods disclosed herein include multiple bandgap systems that contain two or three p-n junctions arranged in a tandem structure. Each junction can be created with semiconductor quantum dot (QD) architectures as described above or similar architectures that can efficiently yield more than one electron-hole pair per absorbed photon. The ability to generate more than one electron-hole pair per absorbed photon is denominated as Multiple Exciton Generation (MEG), and has been confirmed by research. In addition the devices and methods disclosed herein can achieve unexpected high efficiencies through the use of MEG capable semiconductor quantum dot architectures which are photoexcited with concentrated sunlight.

Detailed balanced thermodynamic calculations demonstrate that solar concentration can produce surprisingly high enhanced efficiencies for converting solar irradiance into electrical or chemical free energy if the photoelectrodes contain QD arrays that exhibit MEG compared to photoelectrodes consisting of bulk semiconductors. Thus, for example, if a QD based device exhibits MEG with a threshold photon energy equal to 2.5 times the semiconductor bandgap and increases linearly after the threshold is passed, a condition that is close to present experimental observations, and the solar concentration is 500×, the maximum thermodynamic conversion efficiency is 65% for a single bandgap absorber. Specific embodiments meeting these criteria are described in detail below. This greatly enhanced efficiency compares to a theoretical maximum of 32% for a normal bulk semiconductor photoconverter. If the threshold photon energy can be reduced to 2 bandgaps then the maximum thermodynamic conversion efficiency rises to 75%. However, the QD bandgap for these high maximum efficiencies are very small (˜0.2 eV) thus, tandem structures are typically required to obtain the needed photovoltage for redox solar fuel generation chemistry if only a single bandgap QD is used.

### Detailed Balance Calculations for Unconcentrated Sunlight

A detailed balance model can be used to calculate the power conversion efficiency of single gap and multi-gap tandem solar conversion devices which employ absorbers capable of MEG after photon absorption. The MEG effect is also referred to as carrier multiplication after the excitons are dissociated and collected. Examples of carrier multiplication absorbers include molecular chromophores which can undergo efficient singlet fission (SF) or semiconductor QDs with efficient MEG. The detailed balance model may be applied as detailed below to calculate the efficiency of single gap and multiple gap tandem PEC photoelectrolysis conversion devices (PEC device) having various combinations of MEG absorbers. A representative, but not-exclusive PEC device is a solar driven photoelectrolysis device for the production of H₂. Since the free energy change per electron transferred for H₂O splitting (1.23 V) is the about the same for many CO₂ reduction reactions with H₂O to form fuel (1.21 V for CH₃OH formation and 1.24 V for glucose formation), the thermodynamic conversion efficiency calculations described in detail below for H₂O splitting are applicable to other solar fuel generation reactions as well.

In general, the current versus voltage dependence for a single threshold photoconversion device is written as:

J(V,E_{g})=J_{G}(E_{g})−J_{R}(V,E_{g}) (1)

Where J_{G} is the photogenerated current, J_{R} is the recombination current associated with radiative emission, E_{g} is the absorption threshold or band gap of the absorber and V is the photovoltage generated by the cell. Expressions for the photogenerated current, J_{G}, and recombination current, J_{R} for a single gap cell are written as:

$$\begin{matrix} {J}_{G} \text{?} \text{?} = q {\int }_{{E}_{g}}^{{E}_{max}} Q Y \text{?} Γ \text{?} d E & ( 2 ) \\ {J}_{R} ( V , {E}_{g} ) = q g {\int }_{{E}_{g}}^{∞} \frac{Q Y \text{?} E {\text{?}}^{2}}{exp ( \frac{E - q Q Y \text{?} V \text{?}}{k T} ) - 1} d E & ( 3 ) \\ \text{?} \text{indicates text missing or illegible when filed} & \end{matrix}$$

Where E is the photon energy, q is the electronic charge, k is Boltzmann's constant, T is the temperature of the device (typically T=300K in this disclosure) and g=2π/c²h³, where c is the speed of light in vacuum and h is Plank's constant. The quantum yield, QY(E), allows for the generation and recombination of multiple charge pairs per photon over the appropriate energy range. In the following discussion, the ASTM (American Society for Testing and Materials) G-173-3 Reference AM1.5G solar spectrum is used as the illumination source; (E) is the photon flux associated with the AM1.5G spectrum. Eₘₐₓ is the maximum photon energy in the solar spectrum, (for AM1.5G, Eₘₐₓ=4.428 eV). For practical purposes, Eₘₐₓ˜4 eV, because the integrated solar current above 4 eV in the standard AM1.5G spectrum is only ˜5 A/cm². In Equation (2) carrier generation from ambient blackbody radiation becomes important for E_{g} less than ˜0.2 eV. Implicit in Equations (1)-(3) are the assumptions of the detailed balance model: all photons with energy greater than the absorption threshold are absorbed, the quasi-Fermi level separation is constant and equal to V across the device, which is equivalent to infinite carrier mobility, and the only recombination mechanism acting on the model is radiative recombination. The chemical potential of the emitted photons is qVQY(E), as required by thermodynamics.

For the production of stored chemical energy as H₂ from water splitting the photon conversion efficiency is written as

η_{H}_{₂} [symbol] _{H}_{₂}/P_{IN} (4)

Where E_{H}_{₂}=1.23 V, which is the minimum thermodynamic potential required for water splitting at 300K. In actual water splitting devices, the operating or bias point of the cell, V, will be larger than E_{H}_{₂} by the sum of the anode and cathode overpotentials and the resistive potential drop of the electrolyte. Vₒ is used to denote the sum of these overpotentials (losses) herein. Then, the operating voltage is

V=Vₒ+E_{H}₂ (5)

The maximum efficiency for a single gap device with a given absorption threshold and QY can be found from the above equations by maximizing the efficiencies with respect to the operating voltage V. Maximum efficiencies calculated in this manner are shown in FIG. 4 for a single bandgap absorber without MEG. In particular, FIG. 4 illustrates the calculated conversion efficiency versus bandgap for a single gap water splitting absorber without solar concentration and without MEG calculated for different values of the cell overvoltage (Vo) ranging from 0 to 0.8V in increments of 0.2 V. Vo represents the sum of the cathodic and anodic overpotentials. Overpotentials and overvoltages are the additional electrical potentials (i.e., voltages) required above the minimum thermodynamic potential value to drive the given oxidation-reduction reaction at acceptable reaction rates. The value of the overvoltage increases with the reaction rate or electrochemical current. For the ideal case of Vo=0 V, a minimum bandgap of ˜1.5 eV is required for splitting water because the photovoltage is always <Eg. Also shown for comparison is the typical single gap PV efficiency curve.

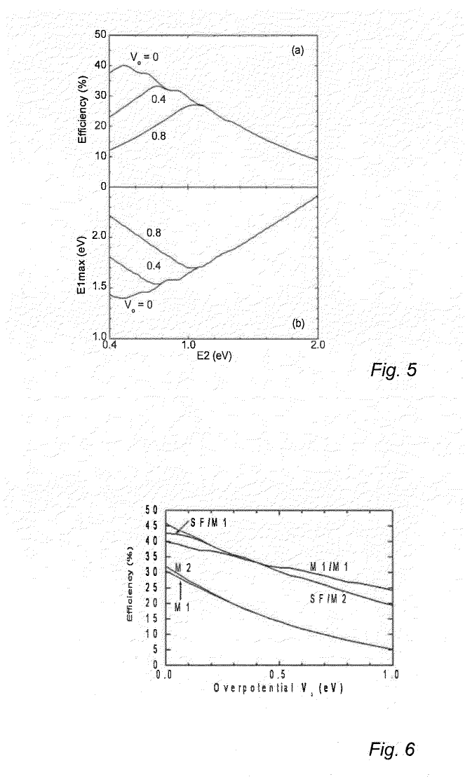

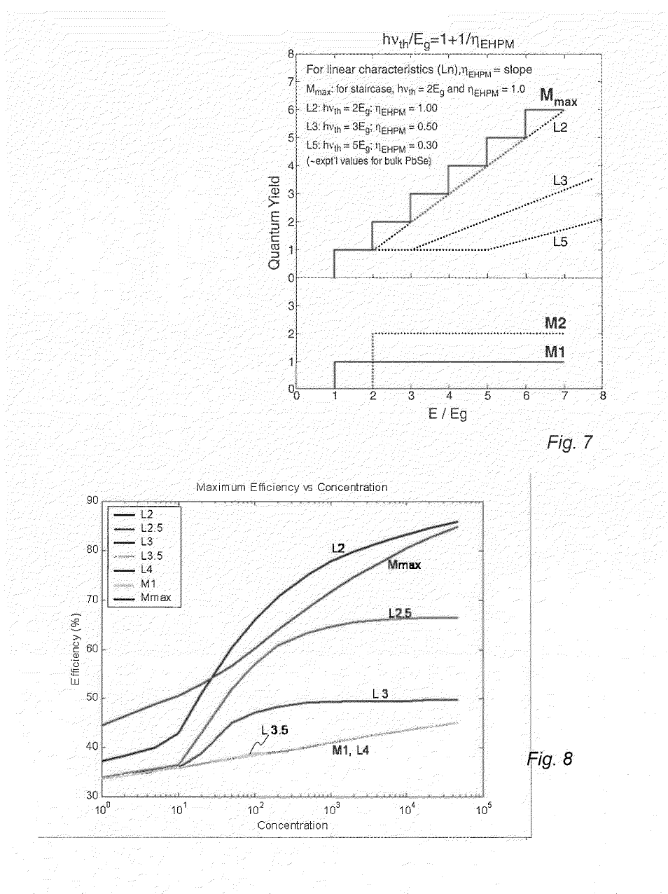

Tandem photoelectrochemical (PEC) devices have the potential to increase the efficiency of solar driven water splitting or other solar fuel reactions, with a limiting value of ˜41% calculated for normal QY=1 absorbers. Providing MEG or SF in either or both of the cells can be expected to increase the available current while maintaining a sufficiently high potential to drive the water splitting reaction, thereby increasing the overall conversion efficiency. FIGS. 5 and 6 illustrate conversion efficiencies in tandem cells where M1 is defined as a photoconversion absorber without MEG or SF and M2 refers to an absorber exhibiting a constant two excitons per absorbed photon at photon energies twice the bandgap and above, or SF produces two excitons per photon at twice the molecular bandgap (i.e. through HOMO-LUMO transition).

FIGS. 5-6 demonstrate the strong dependence of conversion efficiency on cell overvoltage, and hence the importance of catalysis to reduce overvoltage and maximize efficiency. In particular, FIG. 5 illustrates the maximum water splitting conversion efficiency versus bandgap of a bottom cell, E2, for a two-gap series connected tandem device with M1 top and bottom absorbers (graph (a)) and the corresponding value of the top cell bandgap, E1max (graph (b)). Efficiency and E1max curves are shown for three values of overpotential, Vo=0 V, 0.4 V and 0.8 V. FIG. 6 illustrates H₂O splitting device efficiencies at one sun as a function of the overpotential, Vo, for single bandgap absorbers (bottom curves) and 2 absorbers in tandem (top curves). Without solar concentration the largest increase in efficiency is from the tandem structure (41% vs. 31% at V₀=0). It is important to note that carrier multiplication through SF or MEG only improves efficiency with Vo<0.4 V.

In the following analysis, MEG characteristics are defined by the threshold energy (hυ_{MEG}) required by absorbed photons to initiate MEG and the efficiency of MEG after the threshold is passed (η_{MEG}); the latter efficiency, η_{MEG}, is equal to the number of additional excitons created per additional bandgap of absorbed energy beyond the MEG threshold. It has been shown that hυ_{MEG} and η_{MEG} are related by:

(hυ_{MEG}/E_{g})=1 +(1/η_{MEG}) (6)

and that:

QY=((hυ/E_{g})−1))η_{MEG} (7)

Thus, the MEG efficiency increases linearly with (hυ/E_{g}) after the MEG threshold is passed, and a plot of QY vs (hυ/E_{g}) has a slope of η_{MEG} and an x-intercept at QY=1 equal to (hυ_{MEG}/E_{g})—the MEG threshold. Various MEG characteristics are shown in FIG. 7. In FIG. 7, M1 is defined as a normal cell with no MEG and an electron-hole pair threshold at the bandgap (Eg) and maximum QY always equal to=1. Furthermore, Mmax is defined as the ideal maximum MEG characteristic with a MEG staircase function starting at (hυ_{MEG}/E_{g})=2 and creating one additional electron-hole pair upon each additional bandgap of excitation. L(n) is defined as the MEG cases with n defining the threshold value of (hυ_{MEG}/E_{g}) (ie, L2=threshold of 2E_{g}, L3=threshold of 3E_{g}, etc); the corresponding η_{MEG} can be calculated from Equation 6 above.

When MEG devices are operated in the presence of solar concentration, the maximum thermodynamic efficiencies of converting solar radiation to electrical or chemical free energy increase very dramatically with solar concentration compared to normal cells that do not exhibit MEG. These dramatic increases in efficiency were not expected based upon the results known to be obtainable with bulk semiconductor materials and solar concentration as noted above.

### Detailed Balance Calculations for Concentrated Sunlight

Calculations of the maximum thermodynamic conversion efficiencies for solar photoconversion for various MEG characteristics as a function of solar concentration are illustrated in FIG. 8. It is apparent that devices that exhibit MEG with thresholds from 2E_{g} to 3E_{g} show dramatic increases in conversion efficiency with solar concentration compared to absorbers that do not exhibit MEG (M1). Absorbers with MEG thresholds>3E_{g} do not show exceptional enhancement over M1. Thus for example, for L2.5 at 100× solar concentration, the theoretical maximum efficiency for water splitting is approximately 55% compared to approximately 36% for a normal solar cell without MEG. If the MEG threshold can be reduced to 2E_{g} as shown in FIG. 8, L2, the maximum efficiency at 100× solar concentration is approximately 68%.

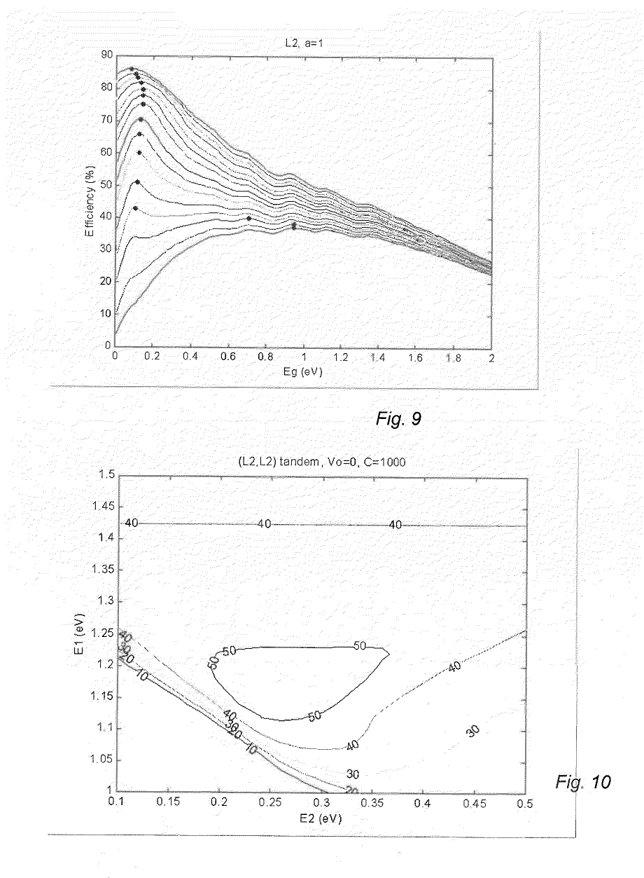

Thus, as shown in FIG. 8, the MEG threshold of a system at a certain solar concentration determines the maximum possible efficiency. As shown in FIG. 9, the solar concentration increases the optimum QD bandgap (indicated by the dot marking the peak efficiency for each curve) shifts to lower values. Accordingly, the optimum bandgaps for solar concentrations less than or equal to 10× are less than ˜0.2 eV. These results are shown in FIG. 9 for the case of L2. In particular, FIG. 9 illustrates the conversion efficiency versus Eg for various levels of solar concentration for MEG with a threshold of 2Eg. The illustrated curves correspond to concentrations of C=1, 2, 5, 10, 20, 50, 100, 200, 500, 1K, 2K, 5K, 10K, 20K, 46K from top to bottom. The peak efficiency (indicated by diamond markers) shifts to lower Eg values at higher solar concentration values. It is believed that this behavior occurs because with bandgaps less than 0.15 eV, the generation of electron-hole pairs via thermal excitation of the ambient becomes very significant and is amplified with MEG and solar concentration.

For PV devices, it is acceptable or desirable to use small bandgap semiconductors that exhibit MEG at high solar concentration to achieve very high conversion efficiencies. The small voltages generated can be increased as is typical in higher voltage PV cells by connecting a suitable number of cells in series.

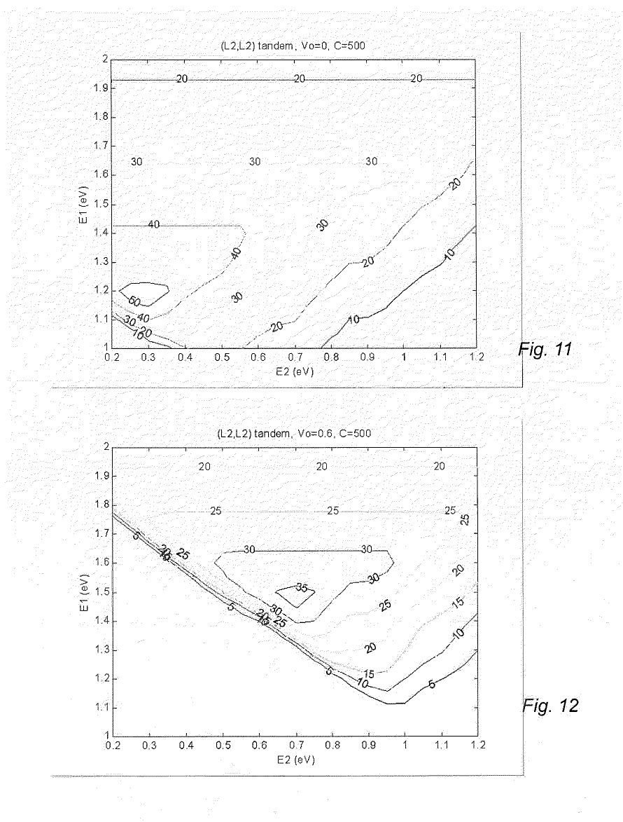

However, a photovoltage greater than 1.23 V is required to split H₂O or drive similar solar fuel reactions. Therefore, a low bandgap (for example <1.6 eV) semiconductor cannot split water. Furthermore, high water splitting conversion efficiencies cannot be achieved with several low bandgap semiconductors placed in electrical series to generate the required photovoltage if the devices are illuminated in parallel because of the large increase in illuminated area. To address this problem, tandem architectures may be used with varying bandgaps in the tandem sequence. An example of the foregoing solution is calculated and illustrated as shown in FIGS. 10-12 for two different bandgaps in tandem and with different overvoltages. [In particular, FIG. 10 shows contour plots of maximum H₂O splitting efficiency of a double bandgap tandem water splitting cell for different values of the two bandgaps with a solar concentration of 1000 and zero overvoltage. Greater than 50% efficiency occurs for a top cell of about 1.23 eV and bottom cell ranging from about 0.2 to 0.3 eV. FIG. 11 shows the same conditions except with a solar concentration of 500. The maximum efficiency is still very high at about 50% with two bandgaps of about 1.2 eV and 0.3 eV

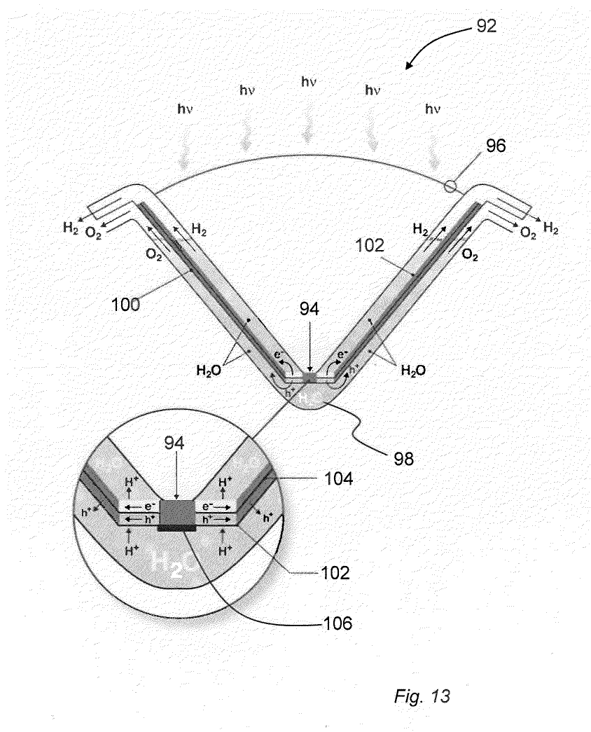

Non-zero overvoltages occur in non-ideal and realistic systems and result in lower efficiencies. This is shown in the FIG. 12 contour plots of maximum H₂O splitting efficiency of a double bandgap tandem water splitting cell for different values of the two bandgaps with a solar concentration of 500× but with an overvoltage of 0.6 V. It may be noted from FIG. 12 that the maximum efficiency drops to about 35% with C=500× and with the two bandgaps now being 1.5 eV and 0.7 eV. In the FIG. 12 case the two bandgaps that maximize efficiency are higher than the cases of zero overvoltage but the maximum efficiency is still above that possible without solar concentration. (31%) (FIG. 6). These results show clearly the maximum benefit of combining MEG with solar concentration depends strongly on lowering the overvoltage as much as possible (<0.5 V) through the use of a good electrocatalyst for water splitting. Thus, to summarize, as illustrated in FIG. 12, non-zero overvoltages will result in lower efficiencies and it is important to use and develop electrocatalysts for solar fuel forming reactions that minimize overvoltage and further maximize efficiency.

### Selected Device Implementations

As described in detail above, concentrated sunlight coupled with MEG in semiconductor nanocrystals may be used to produce photoconversion systems with ultra-high efficiency for converting solar irradiance into solar electricity and solar fuels. However, the use of concentrated sunlight (from 50 to 1000×) will also produce very high effective photogenerated current density in the photoconversion device. For photovoltaic applications this does not produce a problem since any technical challenges resulting from high current densities can be overcome in the same manner as high current densities are dealt with in present PV systems based on solar concentration. For the production of solar fuels however, high photocurrents (up to 20 amps/cm²) would produce large overvoltages for the fuel producing reactions, if the photocurrent was used directly at its high initial value. As described above, the value of any overvoltage has a large influence on conversion efficiency. The overvoltage is a function of the current density and increases with current density according to the Tafel relationship. Current densities of 1 amp/cm² or greater would produce overvoltages of 1V or greater, which would diminish conversion efficiency significantly. One method of preventing high overvoltage for solar fuels formation embodiments is to transfer the large initial photogenerated current to large area electrodes to reduce the current density. Ideally, the surface area of the anodic and cathodic electrodes would be equal to the surface area of the solar concentrator optics. FIG. 13 schematically illustrates how this could be accomplished in one solar fuels producing system.

The system 92 of FIG. 13 includes a semiconductor region 94 comprising nanostructures of a crystalline material as described above. The semiconductor region 94 may be implemented with any of the generalized architectures described above or other suitable architectures. The semiconductor region 94 may include two or more junctions in tandem or other configuration with each junction having a selected bandgap. The nanostructures of crystalline material provide for the generation of multiple excitons for each photon absorbed by the crystalline nanostructure, in response to incident solar radiation. The system 92 further includes one or more optical elements providing for the concentration of sunlight in the semiconductor region. In the illustrated embodiment, the optical element is micro-lens 96. Other configurations of optical concentrating elements are within the scope of this disclosure. The optical element provides for the 50 to 1000 fold concentration of sunlight intensity in the semiconductor region.

The particular system 92 illustrated in FIG. 13 is a fuel producing system that uses electrical energy provided from the semiconductor region to reduce carbon dioxide and/or split water into H₂, a fuel or fuel component and O₂. Thus, the system includes a source of a gas or liquid phase material (i.e., water and/or carbon dioxide) that can be converted to fuel. In the illustrated embodiment, the source is a water source 98. In addition the device includes one or more non-illuminated electrodes 100 and 102 in fluid contact with the water. The electrodes may be implemented with a porous metal structure having cathodic and anodic surfaces separated by an insulating region 104. Alternatively, other electrode architectures may be used in alternative devices. The electrodes may be associated with an oxidation or reduction electrocatalyst on the appropriate surfaces to provide reaction advantages as described above.

The electrodes are placed in an electrical circuit communicating with the semiconductor region. Thus, electric current photogenerated in the semiconductor region can be used to drive the fuel producing reaction. Problems with high current density leading to excessive overvoltage as detailed above may be minimized by providing non-illuminated electrodes with a large surface area and using an appropriate electrocatalyst. In particular the non-illuminated electrodes may have a combined surface area equal to or greater than the area of the concentrator optics.

The embodiment of FIG. 13 further comprises a seal 106 to protect the semiconductor region from water corrosion. As noted above, the electrode structure may be of a porous metal with catalyzed surfaces. A porous metal electrode provides for several important functions including but not limited to: (1) the transport of free electrons and electron holes (after dissociation of excitons within the semiconductor region) to the appropriate anode or cathode surface where water decomposition may occur, (2) proton transport from the anode to cathode, (3) prevention of electron and hole recombination, and (4) H₂ and O₂ bubble separation.

The embodiments disclosed herein are intended to overcome one or more of the limitations described above. The foregoing examples of the related art and limitations related therewith are intended to be illustrative and not exclusive. Other limitations of the related art will become apparent to those of skill in the art upon a reading of the specification and a study of the drawings.

Various embodiments of the disclosure could also include permutations of the various elements recited in the claims as if each dependent claim was a multiple dependent claim incorporating the limitations of each of the preceding dependent claims as well as the independent claims. Such permutations are expressly within the scope of this disclosure.

Several embodiments have been particularly shown and described. It should be understood by those skilled in the art that changes in the form and details may be made to the various embodiments disclosed herein without departing from the spirit and scope of the disclosure and that the various embodiments disclosed herein are not intended to act as limitations on the scope of the claims. Thus, while a number of exemplary aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

What is claimed is:

1. A photoconversion device comprising:
a semiconductor region comprising nanostructures of a crystalline material, the nanostructures of crystalline material providing for the generation of multiple excitons per photon absorbed by the crystalline nanostructure in response to incident solar radiation; and
one or more optical elements providing for the concentration of sunlight in the semiconductor region.

2. The photoconversion device of claim 1 wherein the nanostructures of a crystalline material comprise semiconductor quantum dots, semiconductor quantum wires or semiconductor quantum rods.

3. The photoconversion device of claim 1 wherein the optical elements provide for the 50 to 1000 fold concentration of sunlight intensity in the semiconductor region.

4. The photoconversion device of claim 1 wherein the device is a solar fuel generation device and the semiconductor region further comprises at least two semiconductor junctions having different bandgaps arranged in a tandem sequence.

5. The photoconversion device of claim 1 wherein the device is a solar fuel generation device further comprising:
a source of a gas or liquid phase material which is converted to a fuel through an endoergic electrochemical oxidation-reduction reaction; and
one or more non-illuminated electrodes in fluid contact with the source of a gas or liquid phase material, wherein the electrodes are in electrical communication with the semiconductor region and the semiconductor region provides electrical energy to the electrodes to drive the endoergic reaction in response to incident solar radiation.

6. The photoconversion device of claim 5 further comprising the non-illuminated electrodes having a total surface area greater than or equal to a total surface area of the concentrator optics.

7. The photoconversion device of claim 5 further comprising a seal isolating the semiconductor region from fluid contact with the gas or liquid phase material.

8. The photoconversion device of claim 5 further comprising an electrocatalyst operatively associated with at least one of the one or more non-illuminated electrodes.

9. The photoconversion device of claim 1 wherein the device is a photovoltaic cell.

10. A method of photoconversion comprising:
providing a semiconductor region comprising nanostructures of a crystalline material;
providing one or more optical elements configured to concentrate sunlight in the semiconductor region; and
illuminating the semiconductor region with concentrated sunlight causing the generation of multiple excitons per photon absorbed by the crystalline nanostructures.

11. The method of photoconversion of claim 10 further comprising:
dissociating an exciton to form free carriers; and
collecting the free carriers.

12. The method of photoconversion of claim 10 wherein the nanostructures of a crystalline material comprise at least one of semiconductor quantum dots, semiconductor quantum wires or semiconductor quantum rods.

13. The method of photoconversion of claim 10 wherein the one or more optical elements provide for a 50 to 1000 fold increase in sunlight intensity in the semiconductor region.

14. A method of producing a fuel comprising:
providing a semiconductor region comprising nanostructures of a crystalline material;
providing one or more optical elements configured to concentrate sunlight in the semiconductor region;
illuminating the semiconductor region with concentrated sunlight causing the generation of multiple excitons per photon absorbed by the crystalline nanostructures;
dissociating an exciton to form free carriers;
collecting the free carriers as a photogenerated current; and
driving an endoergic electrochemical oxidation-reduction fuel producing reaction with the photogenerated current.

15. The method of producing a fuel of claim 14 wherein the nanostructures of a crystalline material comprise at least one of semiconductor quantum dots, semiconductor quantum wires or semiconductor quantum rods.

16. The method of producing a fuel of claim 14 wherein the one or more optical elements provide for a 50 to 1000 fold increase in sunlight intensity in the semiconductor region.

17. The method of producing a fuel of claim 14 wherein the step of driving an endoergic fuel producing reaction comprises:
providing a source of a gas or liquid phase material which is to be converted to a fuel through the endoergic reaction; and
providing one or more non-illuminated electrodes in fluid contact with the source of a gas or liquid phase material, wherein the electrodes are in electrical communication with the semiconductor region and photogenerated current.

18. The method of producing a fuel of claim 17 further comprising providing non-illuminated electrodes having a total surface area greater than or equal to the a total surface area of the concentrator optics.

19. The method of producing a fuel of claim 17 further comprising isolating the semiconductor region from contact with the gas or liquid phase material.

20. The method of producing a fuel of claim 17 further comprising associating an electrocatalyst with at least one of the one or more non-illuminated electrodes.
